(19) United States
(12) Patent Application Publication
(10) Pub. No.: US 2010/0271132 A1
(43) Pub. Date: Oct. 28, 2010

(54) Amplifier circuit with resistive current limitter

(75) Inventor: Tachio Yuasa, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/662,514

(22) Filed: Apr. 21, 2010

(30) Foreign Application Priority Data
Apr. 22, 2009 (JP) 2009-104453

(51) Int. Cl. H03F 3/16

(52) U.S. Cl. 330/277

(57) ABSTRACT

An amplifier circuit includes first transistor of first conductivity type having source connected to first power supply, while having gate connected to input terminal and drain connected to output terminal; transistor of second conductivity type having source connected to second power supply and drain connected to the output terminal; second transistor of the first conductivity type whose source and gate are connected to the source and gate of the first transistor of the first conductivity type, respectively; resistor whose one end connected to drain of the second transistor of the first conductivity type, and an output control circuit; current input terminal connected to the opposite end of the resistor; and voltage output terminal connected to the gate of the transistor of the second conductivity type. The output control circuit controls the gate voltage of the transistor of the second conductivity type based on the input current of the current input terminal.

### CROSS-REFERENCE TO RELATED APPLICATION

This application is based upon and claims the benefit of the priority of Japanese patent application No. 2009-104453 filed on Apr. 22, 2009, the disclosure of which is incorporated herein in its entirety by reference thereto.

### TECHNICAL FIELD

This invention relates to an amplifier circuit and, more particularly, to an amplifier circuit that uses complementary transistors including a transistor of the first conductivity type and another transistor of the second conductivity type, and that amplifies an input signal to an output signal.

### BACKGROUND

In amplifier circuits which amplify input signal to output signal, not only portion related with output voltage or output current directly but also other portion must work together. The power consumption of whole circuit is required smaller. Furthermore, amplifier circuit is required that voltages or currents range of input signal and output signal wider, and amplifier circuit is required to be fabricated with less kinds of elements.

FIG. 1 describes a block diagram of a conventional amplifier circuit shown in Patent Document 1. Referring to FIG. 1, M2, M5 denote N-channel MOS transistors (FETs), M1, M4 denote P-channel MOS transistors (FETs) and M3 denotes an N-channel depletion (normally-on) MOS transistor (FET). The MOS transistors other than M3 are all enhancement (normally-off) MOS transistors. In FIG. 1, in denotes a signal input terminal, out denotes a signal output terminal and VDD, VSS denote power supplies. A class AB output control circuit 150 is indicated in a block form. FIG. 2 describes an under layer circuit diagram of a circuit, shown in FIG. 3 of Patent Document 1, and showing details of the inner circuit configuration of a class AB output control circuit 150.

The circuit of FIG. 1 is designed for the gate voltage of the output driving P-channel MOS transistor M4 to swing close to VSS and includes the class AB output control circuit for the gate voltage of the output driving N-channel MOS transistor M5 to swing close to VDD. Patent Document 1 states that the input signal voltage applied to the input terminal in is amplified by both the P-channel MOS transistor M4 and the N-channel MOS transistor M5, which operate class AB, and that both the source current and the sink current amount to large value.

The role of the N-channel depletion MOS transistor M3 is to limit the pass-through current that flows from the power supply VDD to the power supply VSS via P-channel MOS transistor M1 and N-channel MOS transistor M2 in case that the voltage of the input signal in is low.

[Patent Document 1] JP Patent Kokai Publication No. JP2002-261550A

### SUMMARY

The above Patent Document is incorporated herein by reference thereto. The following analysis is given by the present inventor. The N-channel depletion MOS transistor M3 is provided for limiting the current of the P-channel MOS transistor M1. At the same time, the N-channel depletion MOS transistor M3 determines the current flowing into an initial stage of current mirror circuit in the class AB output control circuit 150 (see an N-channel depletion MOS transistor 110 and a current mirror circuit made up of N-channel MOS transistors 104, 103 of FIG. 2). The class AB output control circuit 150 controls the gate voltage of the N-channel MOS transistor M5 in response to the value of the above current. However, the value of the current flowing through the N-channel depletion MOS transistor M3 is saturated at the prescribed voltage drop across the drain and source of the transistor by the transistor characteristic. The saturation voltage as well as the current that flows in saturation is deeply influenced by e.g., the threshold voltage of the depletion transistor. In general, variations of the drain current of a MOSFET, affected by such conditions as manufacturing tolerances, temperatures or power supply voltages, are in an extremely broad range of around −50% to +100%. In the class AB output control circuit, the current in flowing through the output transistor M5 is controlled by the current flowing through this N-channel depletion MOS transistor M3. Thus, if the current flowing through the N-channel depletion MOS transistor M3 suffers from significant variations, the entire amplifier circuit declines in performance, such as accuracy in controlling the power supply current.

In one aspect or mode, the present invention provides an amplifier circuit including a first transistor of a first conductivity type, a transistor of a second conductivity type, a second transistor of the first conductivity type, a resistor and an output control circuit. The first transistor of the first conductivity type has a source connected to a first power supply, while having a gate connected to an input terminal and having a drain connected to an output terminal. The transistor of the second conductivity type has a source connected to a second power supply, while having a drain connected to the output terminal. The second transistor of the first conductivity type has a source connected to the first power supply, while having a gate connected to the input terminal. The resistor has one end connected to a drain of the second transistor of the first conductivity type. The output control circuit has a current input terminal connected to the opposite end of the resistor, while having a voltage output terminal connected to the gate of the transistor of the second conductivity type. The output control circuit controls the gate voltage of the transistor of the second conductivity type based on an input current at the current input terminal.

In another aspect or mode, the present invention provides an amplifier circuit including a transistor of a first conductivity type, a resistor and a transistor of a second conductivity type. The transistor of the first conductivity type has a source connected to a first power supply, while having a gate connected to an input terminal. The resistor has one end connected to the drain of the transistor of the first conductivity type. The transistor of the second conductivity type has a source connected to a second power supply, while having a drain and a gate connected to the opposite end of the resistor.

The meritorious effects of the present invention are summarized as follows. According to the present invention, the current flowing through the transistor of the first conductivity is determined by a resistor. It is thus possible to adjust the value of the current flowing in the transistor of the first conductivity type with high accuracy.

### BRIEF DESCRIPTIONS OF THE DRAWINGS

FIG. 1 is a block diagram of a conventional amplifier circuit described in Patent Document 1.

FIG. 2 is a detailed circuit diagram of the conventional amplifier circuit described in Patent Document 1.

FIG. 3 is a block diagram of an amplifier circuit according to an Example of the present invention.

FIG. 4 is a block diagram of an amplifier circuit according to another Example of the present invention.

### PREFERRED MODES

The schemata of the present invention will now be described while having reference to the drawings when necessary. It is noted that the drawings referred to in the explanation of the schemata and reference numerals used therein are for the sake of illustration only and are not intended to limit possible alterations of the exemplary embodiment of the invention.

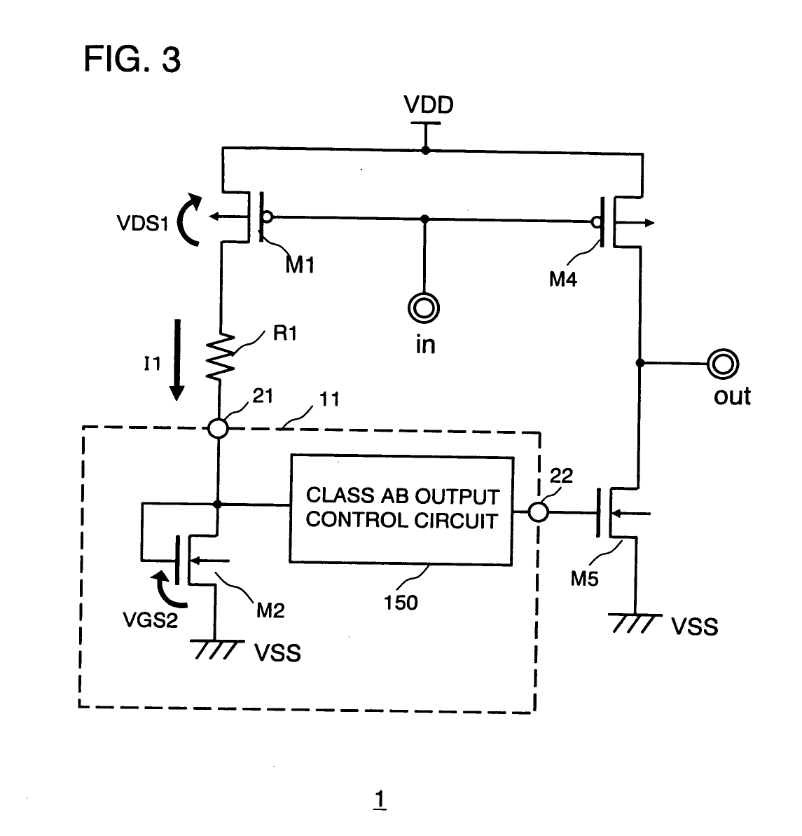

An amplifier circuit 1 of the exemplary embodiment of the present invention includes a first transistor of the first conductivity type M4, a transistor of the second conductivity type M5, a second transistor of the first conductivity type M1, a resistor R1 and an output control circuit 11, as shown for example in FIG. 3. The first transistor of the first conductivity type M4 has a source connected to the first power supply VDD, while having a gate connected to an input terminal in and having a drain connected to an output terminal out. The transistor of the second conductivity type M5 has a source and a drain connected to the second power supply VSS and to the output terminal out, respectively. The second transistor of the first conductivity type M1 has a source and a gate connected to the first power supply VDD and to the input terminal in, respectively. The resistor R1 has one end connected to the drain of the second transistor of the first conductivity type M1. The output control circuit 11 includes a current input terminal 21 connected to the opposite end of the resistor R1, while including a voltage output terminal 22 connected to the gate of the transistor of the second conductivity type M5. The output control circuit controls the gate voltage of the transistor of the second conductivity type M5 based on the input current of the current input terminal 21. In the above configuration, the current flowing through the second transistor of the first conductivity type M1 and the current input terminal 21 of the output control circuit 11 is determined by the resistor R1. It is noted that the current value of the current flowing through the resistor is proportionate to the voltage across its terminals, in contradistinction from the case of a depletion transistor, and is not saturated in the usual voltage range. In a semiconductor device, the resistor is realized by a diffusion resistance or polysilicon, and suffers variations which may be suppressed to around −20% to +20%, for example. It is thus possible to suppress the current flowing through the second transistor M1 of the first conductivity type with high accuracy and to control the gate voltage of the transistor of the second conductivity type M5. They affect improving the performance overall of the amplifier circuit.

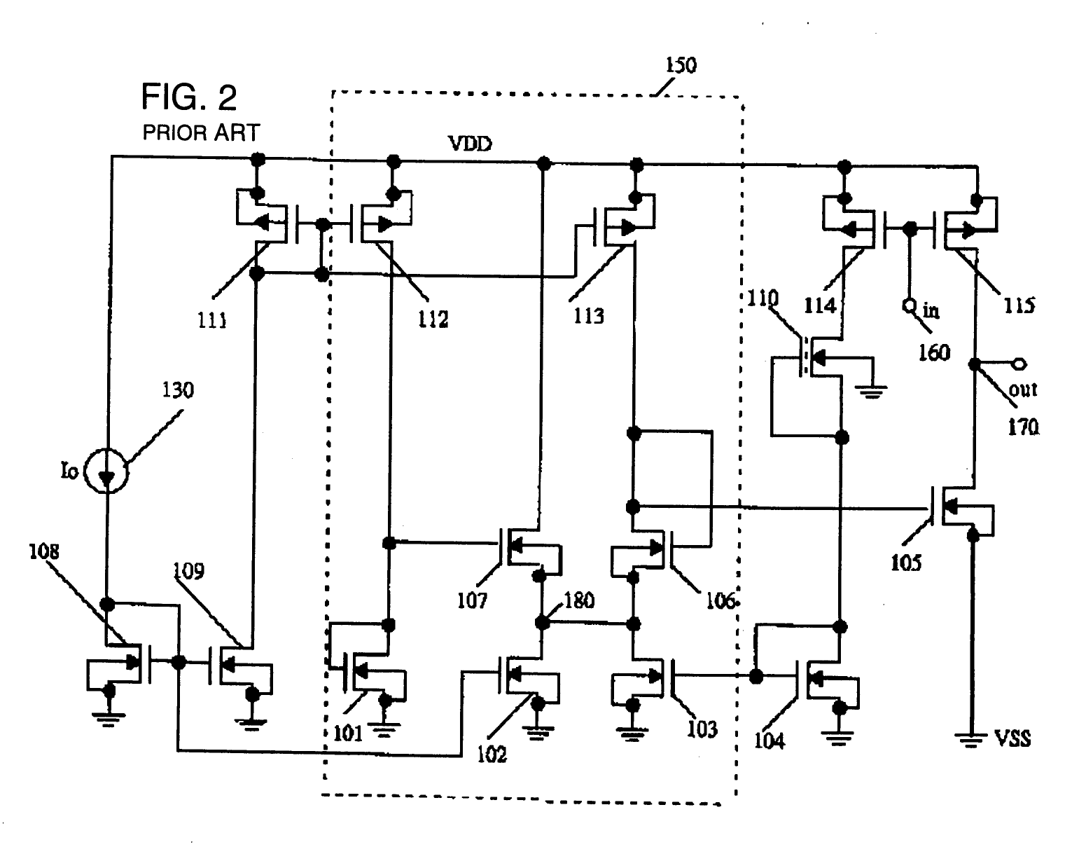

In the amplifier circuit 1 of the exemplary embodiment, the output control circuit 11 includes a current mirror circuit, which is connected to the current input terminal 21, as shown for example in FIGS. 2 and 3. It is noted that, if the circuit of FIG. 2 is used as the class AB control circuit 150, there formed a current mirror circuit having an N-channel MOS transistor M2 of FIG. 3 as an input transistor of the current mirror circuit and having an N-channel MOS transistor 103 of FIG. 2 as an output transistor.

In the amplifier circuit 1 of an exemplary embodiment, the output control circuit 11 exercises control so that, if an input current I1 is increased or decreased, the absolute value of the gate-source voltage of the transistor of the second conductivity type M5 is decreased or increased, respectively, as shown for example in FIG. 3.

In the amplifier circuit 1 of an exemplary embodiment, if the transistor of the second conductivity type M5 is defined as the first transistor of the second conductivity type M5, the output control circuit 11 includes a second transistor of the second conductivity type M2. This second transistor of the second conductivity type M2 has a gate and a drain connected to the current input terminal 21, while having a source connected to the second power supply VSS.

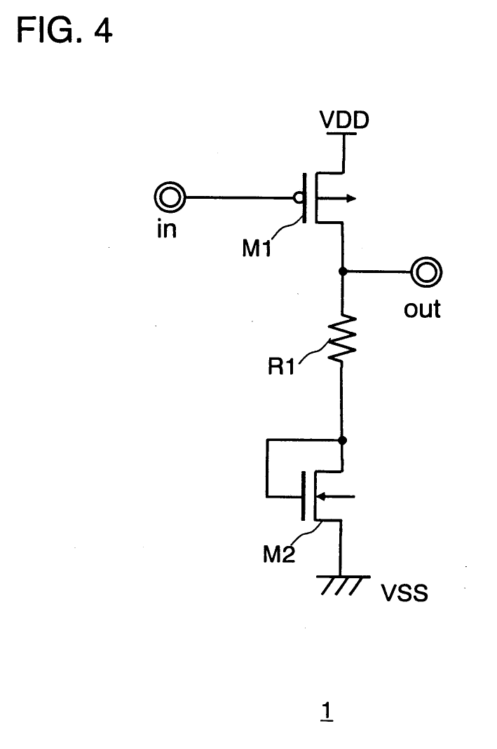

Further, the amplifier circuit 1 of an exemplary embodiment includes a transistor of the first conductivity type M1, a resistor R1 and a transistor of the second conductivity type M2, as shown for example in FIGS. 3 and 4. The transistor of the first conductivity type M1 has a source connected to the first power supply VDD, while having a gate connected to the input terminal in. The resistor R1 has one end connected to the drain of the transistor of the first conductivity type M1. The transistor of the second conductivity type M2 has a source connected to the second power supply VSS, while having a drain and a gate connected to the other end of the resistor R1.

Moreover, in the amplifier circuit 1 of the exemplary embodiment, the drain of the transistor of the first conductivity type M1 and one end of the resistor R1 are connected to an output terminal of the amplifier circuit, as shown in FIG. 4.

In addition, in the amplifier circuit 1 of the exemplary embodiment, the transistors of the first conductivity type (M1, M4) and the transistors of the second conductivity type (M2, M5) are all MOS transistors, as shown in FIGS. 3 and 4. Examples of the present invention will now be described in detail with reference to the drawings.

### Example 1

FIG. 3 describes a block diagram of the amplifier circuit 1 of Example 1. Referring to FIG. 3, the P-channel MOS transistor M4 has a source connected to the power supply VDD, while having a gate connected to the input terminal in and having a drain connected to the output terminal out. The P-channel MOS transistor M1 has a source connected to the power supply VDD, while having a gate connected to the input terminal in and having a drain connected to one end of the resistor R1. The opposite end of the resistor R1 is connected to the current input terminal 21 of the output control circuit 11. The voltage output terminal 22 of the output control circuit 11 is connected to the gate of the N-channel MOS transistor M5. The output control circuit 11 controls the gate voltage of the N-channel MOS transistor M5 based on the current flowing through the current input terminal 21. The N-channel MOS transistor M5 has a source connected to the power supply VSS, while having a drain connected to the output terminal out.

The output control circuit 11 includes, inside, an N-channel MOS transistor M2 and a class AB output control circuit 150. The N-channel MOS transistor M2 has a source connected to the power supply VSS, while having a gate and a drain connected to the input terminal 21 and to an input of the class AB output control circuit 150. The output of the class AB output control circuit 150 is connected to the voltage output terminal 22. The class AB output control circuit 150 may have the same circuit configuration as that of the conventional class AB output control circuit 150 shown in FIG. 2.

The operation of the amplifier circuit 1 of FIG. 3 is hereby described. When the voltage at the input terminal in is sufficiently high and close to VDD, no current flows between the source and the drain of the P-channel MOS transistor M4 which is an output transistor. Likewise, no current flows between the source and the drain of the P-channel MOS transistor M1. The source of the P-channel MOS transistor M1 is connected together to the source of the P-channel MOS transistor M4, and the gate of the P-channel MOS transistor M1 is connected together to the gate of the P-channel MOS transistor M4. Hence, no current flows into the current input terminal 21 of the output control circuit 11 to which the transistor M1 is connected via the resistor R1. When the current flowing into the output control circuit 11 via the current input terminal 21 is large, the output control circuit 11 provides a high level at the voltage output terminal 22. Therefore, the N-channel MOS transistor M5 is turned on and the sink current of the N-channel MOS transistor M5 from the output terminal out to the power supply VSS flows.

Subsequently, when the voltage at the input terminal in becomes slightly lower from VDD, the P-channel MOS transistor M4, as an output transistor, is turned on. Hence, the source current flows from the power supply VDD via the P-channel MOS transistor M4 to the output terminal out. Then, analogously to the P-channel MOS transistor M4, the P-channel MOS transistor M1 is turned on. The current thus flows via the resistor R1 to the current input terminal 21 of the output control circuit 11. The output control circuit 11 then causes fall the gate voltage of the N-channel MOS transistor M5 in proportion to the increase of the current delivered from the current input terminal 21. The sink current that flows from the output terminal out via the N-channel MOS transistor M5 to the power supply VSS is thus decreased. That is, as the voltage applied from the input terminal in becomes lower, the source current that flows from the power supply VDD to the output terminal out is increased, while the sink current that flows from the output terminal out via the N-channel MOS transistor M5 to the power supply VSS is decreased.

When the voltage at the input terminal in becomes further lower, the on-resistance of the P-channel MOS transistor M4 is further decreased. Hence, the source current that flows from the power supply VDD via the P-channel MOS transistor M4 to the output terminal out tends to be increased further. Accordingly, the current flowing between the source and, the drain of the P-channel MOS transistor M1 is also increased, which cause the current flowing via the resistor R1 to the current input terminal 21 of the output control circuit 11 increased. If the current flowing at the current input terminal 21 into the output control circuit 11 exceeds a preset current value, the voltage output terminal provides voltage between less than the threshold value of the N-channel MOS transistor and almost equal to OV (VSS). This causes the N-channel MOS transistor M5 to be turned off, so that the sink current, which flowed from the output terminal out via the source-drain current path of the N-channel MOS transistor M5 to the power supply VSS, ceases flow.

If the voltage at the input terminal in becomes further lower, the on-resistance of the P-channel MOS transistor M4 is further decreased. The source current that flows via the P-channel MOS transistor M4 from the power supply VDD to the output terminal out tends to be further increased. On the other hand, the current flowing through the P-channel MOS transistor M1 is limited by the resistance R1 such that the current does not exceed beyond a preset constant value. Even in such case, the amount of the current that flows via the resistor R1 to the current input terminal 21 of the output control circuit 11 is sufficient to output a low level from the voltage output terminal 22 to turn off the N-channel MOS transistor M5. Hence, no sink current flows from the output terminal out to the power supply VSS via the N-channel MOS transistor M5. It is thus possible to prevent a pass-through current flowing from the power supply VDD to the power supply VSS via the P-channel MOS transistor M4, which is an output transistor, and via the N-channel MOS transistor M5.

In brief, the output control circuit 11 controls the sink current flowing from the output terminal out via the N-channel MOS transistor M5 to the power supply VSS based on the amount of the current flowing via the source-drain current path of the P-channel MOS transistor M1. However, if once the voltage at the input terminal in has exceeded a preset low value and the amount of the current flowing through the P-channel MOS transistor M1 is increased, then no sink current flows through the N-channel MOS transistor M5, it is unnecessary for the current flowing through the P-channel MOS transistor M1 to be further increased. The resistance value of the resistor R1 is determined so that the current flowing through the P-channel MOS transistor M1 will be limited, which is enough for the current flowing into the current input terminal 21 of the output control circuit 11 to provide a low level at the voltage output terminal 22.

If the resistance value of R1 is too large, the amount of the current flowing through the current input terminal 21 of the output control circuit 11 is still small even though the voltage at the input terminal in become low to turn on the P-channel MOS transistor M4. Hence, the N-channel MOS transistor M5 is not turned off, then a pass-through current flows from the power supply VDD to the power supply VSS via the P-channel MOS transistor M4 and the N-channel MOS transistor M5.

On the other hand, if the resistance value of the resistor R1 is too small, a current I1, whose amount is more than effectively needed, flows from the power supply VDD to the power supply VSS via the P-channel MOS transistor M1, resistor R1 and the N-channel MOS transistor M2. In particular, if the voltage at the input terminal in is sufficiently low but the voltage level of the output terminal out has been raised to close to the voltage VDD, the current flowing through the P-channel MOS transistor M4 is limited because the source-drain voltage of the P-channel MOS transistor M4 is low. Conversely, if the resistance value of the resistor R1 is too small, the source-drain voltage of the P-channel MOS transistor M1 is larger than the source-drain voltage of the P-channel MOS transistor M4. Hence, an amount of the current more than determined by the transistor size ratio of the P-channel MOS transistor M1 and the P-channel MOS transistor M4 flows through the P-channel MOS transistor M1. In this case, if there flows an amount of the drain current of the P-channel MOS transistor M1 larger than designed value, such excess drain current scarcely contribute to increasing either the output voltage or the source current, which is wasteful. Therefore, the resistance value of the resistor R1 must be designed as proper value.

The proper value of the resistor R1 may be found by the following calculations. In the circuit of FIG. 3, assuming I1 as the current flowing through the P-channel MOS transistor M1, resistor R1 and the N-channel MOS transistor M2 of the output control circuit 11, I1 is calculated by the following equation (1):

$$I 1 = \frac{VDD - VDS 1 - VGS 2}{R 1} \qquad ( 1 )$$

where VDS1 denotes the drain-source voltage of the P-channel MOS transistor M1 and VGS2 denotes the gate-source voltage of the N-channel MOS transistor M2. Substituting in equation (1) I1 as the required current value for controlling the output control circuit 11, VDD as the power supply voltage, VDS1 and VGS2 as respective MOS transistor characteristics values, the value of R1 can be obtained necessary as a circuit constant. In other words, current I1 can be controlled with relatively accurate using a resistor for the element to limit the current.

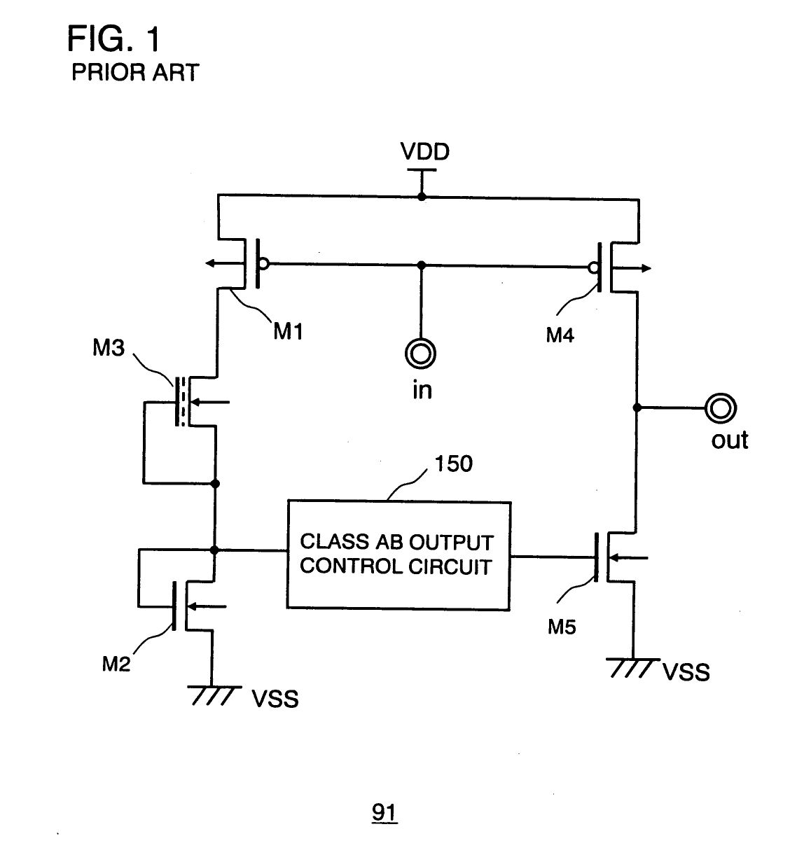

Assuming that an N-channel depletion MOS transistor M3 is used as a component element that limits the current as described in the related art example (FIG. 1), controlling the current value accurately is difficult since the current value I1 flowing through N-channel depletion MOS transistor M3 operating in saturation region is proportional to the square of the subtraction between gate-source voltage and threshold voltage of N-channel depletion MOS transistor M3. In general, the current value of the drain current in a MOS transistor constituted on LSI varies very large e.g. around −50% to +100%, depending on manufacture tolerances, temperatures or power supply voltages. On the other hand, the value of the resistor varies e.g. around −20% to +20%, which is smaller than those in the drain current of the MOS transistor.

Moreover, depletion transistor, used in the related art example (FIG. 1) as a current limiting element, is a kind of not used in the almost CMOS production process. Thus, the related art example requires a production process of providing a depletion transistor and a maintenance process for threshold voltage characteristics of a depletion transistor in addition to the almost CMOS manufacturing process. Conversely, the Example 1 use no depletion transistors, hence it does not require additional manufacturing process or maintenance process like mentioned above.

In FIG. 3, the class AB output control circuit 150 shown in Patent Document 1 is provided in the output control circuit 11, however, the present invention is not limited to this configuration. Any configuration which controls gate voltage of the N-channel MOS transistor M5 based on current flowing at the current input terminal 21 can be applied for the output control circuit 11. In particular, it is desirable that the N-channel MOS transistor M5 is turned on so as to control sink current flowing from the output terminal out to power supply VSS when there scarcely flows current through the current input terminal 21, and that the N-channel MOS transistor M5 is turned off so as to control sink current not flowing from the output terminal out to power supply VSS when the current flowing through the current input terminal 21 has reached some extent value. By this way, N-channel MOS transistor M5 flows sink current when there flows no current from P-channel MOS transistor M4 to the output terminal out, and N-channel MOS transistor M5 is turned off when there flows current flowing through the P-channel MOS transistor M4 to the output terminal out to some extent, namely pass-through current can be suppressed flowing from the power supply VDD to the power supply VSS via source-drain current paths of output transistors, P-channel MOS transistor M4 and N-channel MOS transistor M5.

FIG. 4 describes a block diagram of an amplifier circuit of Example 2. Examples 1 and 2 have common structure which consist of P-channel MOS transistor M1 having source connected to the power supply VDD and gate connected to the input terminal in, resistor R1 having one end connected to the drain of the P-channel MOS transistor M1 and the other end connected to the drain and the gate of the N-channel MOS transistor M2, and N-channel MOS transistor M2 having source connected to the power supply VSS. However, in Example 2, the output terminal out is connected to the drain of the P-channel MOS transistor M1, while it is unnecessary to provide the P-channel MOS transistor M4, N-channel MOS transistor M5 or the class AB output control circuit 150, those which are provided in Example 1. That is, an amplifier circuit may be constructed of a smaller number of component elements. As the circuit of Example 2 operates class A, supply current consumption for output current is larger than of Example 1 but number of component element smaller than half of Example 1. In Example 2 which is provided with resistor R1 between the drain of the P-channel MOS transistor M1 and both the drain and the gate of the N-channel MOS transistor M2 similarly to Example 1, it is possible to limit accurately the amount of the current flowing through the P-channel MOS transistor M1.

In Examples shown in FIGS. 3 and 4, it is P-channel transistor that is used as an output transistor having a gate connected to the input terminal in and having a drain connected to the output terminal out. Besides this construction, such construction can be used that connection of the power supply VDD and the power supply VSS is reversed, conductivity types of all P-channel and N-channel MOS transistors are exchanged, and N-channel MOS transistor is used for the output transistor.

Furthermore, an advantage, that output voltage range or output current range (They are called “dynamic range”.) are expanded, is obtained with the use of the amplifier circuit of the present invention. The MOSFET has such characteristic that it operates the characteristics region called linear region (unsaturated region), the maximum value of drain current declines and the drain internal output resistor measured from drain terminal declines in following equation region assuming VDS as drain-source voltage, VGS as gate-source voltage, and Vth as threshold voltage:

VDS≦VGS−Vth (2)

In other words, the amplifier circuit of the related art suffers such problem that drain current of N-channel depletion MOS transistor M3 declines and this makes the current limited by P-channel MOS transistor M1 much smaller, operation or characteristics of whole circuit consequently become worse when drain-source voltage of N-channel depletion MOS transistor M3 declines to the region represented equation (2). Conversely, using the amplifier circuit of the present invention, since variations of the resistance value of the resistor R1 against changes in the terminal voltage of R1 are extremely small, e.g. popularly a few percent, there appeared no such problem that value of the current limited by the P-channel MOS transistor M1 of Example 1 of FIG. 3 declines or value of voltage gain of the circuit of Example 2 shown in FIG. 4 declines.

In the present disclosure, various modes are possible which includes the following, but not restrictive thereto.

Mode 1: An amplifier circuit as set forth as the one aspect.
Mode 2: In the amplifier circuit according to mode 1, the output control circuit may include a current mirror circuit connected to the current input terminal.
Mode 3: In the amplifier circuit according to mode 1 or 2, the output control circuit may exercise control so that, when the input current is increased, the absolute value of the gate-source voltage of the transistor of the second conductivity type is decreased, and so that, when the input current is decreased, the absolute value of the gate-source voltage is increased.
Mode 4: In the amplifier circuit according to any one of modes 1 to 3, the transistor of the second conductivity type may be defined as a first transistor of the second conductivity type, and the output control circuit may comprise a second transistor of the second conductivity type whose gate and drain are connected to the current input terminal and whose source is connected to the second power supply.
Mode 5: An amplifier circuit as set forth as “another” aspect.
Mode 6: In the amplifier circuit according to mode 5, the drain of the transistor of the first conductivity type and the one end of the resistor may be connected to an output terminal of the amplifier circuit.
Mode 7: In the amplifier circuit according to any one of modes 1 to 6, both of the transistor of the first conductivity type and the transistor of the second conductivity type may be MOS transistors.
Mode 8: In the amplifier circuit according to mode 5, the transistor of the first conductivity type and the transistor of the second conductivity type, respectively, may be defined as a first transistor of the first conductivity type and a first transistor of the second conductivity type, wherein the amplifier circuit further may comprise: a class AB output control circuit having a input terminal connected to the drain and gate of the first transistor of the second conductivity type; a second transistor of the second conductivity type having a gate connected to an output terminal of the class AB output control circuit, having a source connected to the second power supply, and having a drain connected to an output terminal of the amplifier circuit; and a second transistor of the first conductivity type having a source connected to the first power supply, having a gate connected to the input terminal, and having a drain connected to the output terminal.

In the foregoing, explanation has been made of certain specified Examples of the present invention. However, the present invention is not limited to the configuration of the above Examples. It should be noted that variations, modifications or any selected combinations of components and/or elements disclosed that may be within the reach of those skilled in the relevant art may, of course, be comprehended within the scope of the present invention.

What is claimed is:

1. An amplifier circuit comprising:
a first transistor of a first conductivity type having a source connected to a first power supply, having a gate connected to an input terminal and having a drain connected to an output terminal;
a transistor of a second conductivity type having a source connected to a second power supply and having a drain connected to said output terminal;
a second transistor of the first conductivity type having a source connected to said first power supply and having a gate connected to said input terminal;
a resistor having one end connected to a drain of said second transistor of the first conductivity type; and
an output control circuit having a current input terminal connected to the opposite end of said resistor and having a voltage output terminal connected to the gate of said transistor of the second conductivity type; said output control circuit controlling the gate voltage of said transistor of said second conductivity type based on an input current at said current input terminal.

2. The amplifier circuit according to claim 1, wherein
said output control circuit includes a current mirror circuit connected to said current input terminal.

3. The amplifier circuit according to claim 1, wherein
said output control circuit exercises control so that, when said input current is increased, the absolute value of the gate-source voltage of said transistor of said second conductivity type is decreased, and so that, when said input current is decreased, the absolute value of said gate-source voltage is increased.

4. The amplifier circuit according to claim 1, wherein said transistor of said second conductivity type is defined as a first transistor of the second conductivity type,
said output control circuit comprising a second transistor of the second conductivity type whose gate and drain are connected to said current input terminal and whose source is connected to said second power supply.

5. An amplifier circuit comprising:
a transistor of a first conductivity type having a source connected to a first power supply and having a gate connected to an input terminal;
a resistor having one end connected to a drain of said transistor of the first conductivity type; and
a transistor of a second conductivity type having a source connected to a second power supply and having a drain and a gate connected to the opposite end of said resistor.

6. The amplifier circuit according to claim 5, wherein
the drain of said transistor of the first conductivity type and said one end of said resistor are connected to an output terminal of the amplifier circuit.

7. The amplifier circuit according to claim 1, wherein
both of said transistor of the first conductivity type and said transistor of the second conductivity type are MOS transistors.

8. The amplifier circuit according to claim 5, wherein said transistor of the first conductivity type and said transistor of the second conductivity type are defined as a first transistor of the first conductivity type and a first transistor of the second conductivity type, respectively, said amplifier circuit further comprising:
a class AB output control circuit having a input terminal connected to said drain and gate of said first transistor of the second conductivity type;
a second transistor of the second conductivity type having a gate connected to an output terminal of said class AB output control circuit, having a source connected to said second power supply, and having a drain connected to an output terminal of the amplifier circuit; and
a second transistor of the first conductivity type having a source connected to said first power supply, having a gate connected to said input terminal, and having a drain connected to said output terminal.
